(19) United States
(12) Patent Application Publication
(10) Pub. No.: US 2011/0214716 A1
(43) Pub. Date: Sep. 8, 2011

(54) ISOLATED METALLIC FLEXIBLE BACK SHEET FOR SOLAR MODULE ENCAPSULATION

(75) Inventors: Todd Krajewski, Mountain View, CA (US); Jason Corneille, San Jose, CA (US); Shefali Jaiswal, Milpitas, CA (US); Anil Vijayendran, San Jose, CA (US)

(73) Assignee: MIASOLE, Santa Clara, CA (US)

(21) Appl. No.: 13/107,574

(22) Filed: May 13, 2011

Related U.S. Application Data
(63) Continuation of application No. PCT/US2010/034386, filed on May 11, 2010.
Application No. PCT/US2010/034386 is a continuation-in-part of application No. 12/464,721, filed on May 12, 2009, now Pat. No. 7,829,783.
Application No. 12/464,721 is a continuation-in-part of application No. 12/556,460, filed on Sep. 9, 2009, now Pat. No. 7,960,643.

(51) Int. Cl. H01L 31/048

(52) U.S. Cl. 136/251

(57) ABSTRACT

Provided are novel solar modules including electrically isolated moisture barriers. According to various embodiments, the solar modules include two distinct seals: one to electrically isolate the moisture barrier and one to protect photovoltaic cells of the module. Also provided are novel back sheets for solar module encapsulation, and novel solar modules including such back sheets. According to various embodiments, the back sheets are ungrounded and flexible. In certain embodiments, the back sheets include an integrated flexible and electrically isolated moisture barrier. The electrically isolated moisture barrier may be a thin metallic sheet, e.g., an aluminum foil. The electrically isolated, flexible moisture barrier eliminates the need for grounding.

### CROSS REFERENCE TO RELATED APPLICATIONS

This application is a continuation of PCT Application No. PCT/US2010/034386, entitled “ISOLATED METALLIC FLEXIBLE BACK SHEET FOR SOLAR MODULE ENCAPSULATION,” filed 11 May 2010, which claims priority to U.S. patent application Ser. No. 12/464,721, entitled: “ISOLATED METALLIC FLEXIBLE BACK SHEET FOR SOLAR MODULE ENCAPSULATION” filed on 12 May 2009 (now issued as U.S. Pat. No. 7,829,783) and U.S. patent application Ser. No. 12/556,460, also entitled “ISOLATED METALLIC FLEXIBLE BACK SHEET FOR SOLAR MODULE ENCAPSULATION,” filed on 9 Sep. 2009, which are hereby incorporated by reference in their entireties and for all purposes.

### BACKGROUND OF THE INVENTION

Photovoltaic cells are widely used for generation of electricity, with multiple photovoltaic cells interconnected in module assemblies. Such modules may in turn be arranged in arrays and integrated into building structures or otherwise assembled to convert solar energy into electricity by the photovoltaic effect. Individual modules are encapsulated to protect the module components from the environment. A module may be framed, with the frame configured for attachment to a support surface. Framing and encapsulating materials can contribute significantly to the weight and cost of a module.

### SUMMARY OF THE INVENTION

Provided are novel solar modules including electrically isolated moisture barrier. According to various embodiments, the solar modules include two distinct seals: one to electrically isolate the moisture barrier and one to protect photovoltaic cells of the module. Also provided are novel back sheets for solar module encapsulation, and novel solar modules including such back sheets. According to various embodiments, the back sheets are ungrounded and flexible. In certain embodiments, the back sheets include an integrated flexible and electrically isolated moisture barrier. The electrically isolated moisture barrier may be a thin metallic sheet, e.g., an aluminum foil. The electrically isolated, flexible moisture barrier eliminates the need for grounding.

One aspect of the invention relates solar modules that include a transparent front layer; a flexible back sheet including an electrically isolated moisture barrier; a plurality of interconnected photovoltaic cells disposed between the transparent front layer and the flexible back sheet, a first seal isolating the plurality of interconnected photovoltaic cells; and a second seal isolating the moisture barrier, said second seal being distinct from said first seal.

In certain embodiments, the flexible back sheet is a multi-layer flexible back sheet that includes an insulation sheet, the electrically isolated moisture barrier, a back layer and the second seal, with the insulation sheet disposed between the plurality of photovoltaic cells and the moisture barrier, the moisture barrier disposed between the insulation sheet and the back layer, and wherein said second seal includes a bond between the insulation sheet and the back layer and extends around the moisture barrier such that the insulation sheet, back layer and second seal electrically isolate the moisture barrier. In certain embodiments the bond is a polymer adhesive bond.

In certain embodiments, the flexible back sheet is a multi-layer flexible back sheet including an insulation sheet, the electrically isolated moisture barrier and a back layer; with the insulation sheet disposed between the plurality of photovoltaic cells and the moisture barrier, the moisture barrier disposed between the insulation sheet and the back layer, and wherein the back layer has dimensions greater than the moisture barrier and extends past the moisture barrier to enclose an edge of the moisture barrier.

In certain embodiments, the flexible back sheet is a multi-layer flexible back sheet including an insulation sheet, the electrically isolated moisture barrier, a back layer and the second seal; with the insulation sheet disposed between the plurality of photovoltaic cells and the moisture barrier, the moisture barrier disposed between the insulation sheet and the back layer, and the second seal including the perimeter of the back layer.

According to various embodiments, the first seal includes a sealing material surrounding the interconnected photovoltaic cells. Examples of sealing materials include butyl-rubber containing moisture getters or desiccants. In certain embodiments, the first seal includes a bonding between the sealing material and the transparent front layer. In certain embodiments, the sealing material is adhesive. This may be a covalent bonding, an adhesive bonding or other type of bonding. The first seal may include a bonding between the sealing material and the flexible back sheet, e.g., a bonding to between the sealing material one or more layers of the flexible back sheet. This may be a covalent bonding, an adhesive bonding or other type of bonding. Also in certain embodiments, the second seal comprises a bond between the sealing material and the back layer. In certain embodiments, a back layer of the flexible back sheet extends past the insulation sheet to enclose an edge of the insulation sheet.

Other aspects of the invention relates to multi-layer flexible back sheets and solar modules incorporating multi-layer flexible back sheets. One aspect relates to solar modules that include a transparent front layer, a multi-layer flexible back sheet; and a plurality of interconnected photovoltaic cells disposed between the transparent front layer and the multi-layer flexible back sheet. The multi-layer flexible back sheet includes an insulation sheet, an electrically isolated moisture barrier, and a back layer; with the insulation sheet disposed between the plurality of photovoltaic cells and the moisture barrier and the moisture barrier disposed between the insulation sheet and the back layer. The back layer has dimensions greater than the moisture barrier and extends past the moisture barrier to enclose an edge of the moisture barrier.

In certain embodiments, the back layer also extends past the insulation sheet to enclose an edge of the insulation sheet. The back layer may enclose the entire perimeter edge of the moisture barrier and/or insulation sheet or a portion of the perimeter edge. All or part of a perimeter portion of the back layer may be sealed to another module component. In certain embodiments, an edge seal material surrounding the plurality of photovoltaic cells is sealed to the back layer. In certain embodiments, the insulation sheet and back layer are arranged to fully enclose the moisture barrier.

Another aspect of the invention relates to solar modules that include a transparent front layer; a multi-layer flexible back sheet; and a plurality of interconnected photovoltaic cells disposed between the transparent front layer and the multi-layer flexible back sheet. The multi-layer flexible back sheet includes an insulation sheet, an electrically isolated moisture barrier, a back layer and a seal; with the insulation sheet disposed between the plurality of photovoltaic cells and the moisture barrier, the moisture barrier disposed between the insulation sheet and the back layer, and the seal including the perimeter of the back layer and/or a bond to the perimeter of the back layer.

In certain embodiments, the seal includes a bond between the perimeter of the back layer and a second module component. The second module component may be an edge seal material that surrounds the photovoltaic cells, or may be another component. In certain embodiments, the back layer has dimensions greater than the moisture barrier and extends past the moisture barrier to cover the perimeter of the moisture barrier.

According to various embodiments, the transparent front layer may be a rigid material, e.g., a glass plate, or it may be flexible material. The photovoltaic cells may be any type of photovoltaic cells, including but not limited to CIS, CIGS, CdTe or silicon photovoltaic cells.

According to various embodiments, the moisture barrier is a pinhole free conductive material, e.g., pinhole free aluminum foil. The moisture barrier is typically thin, e.g., no more than about 50 microns thick, or no more than 25 microns thick. Other thicknesses may be used as appropriate to provide a flexible moisture barrier.

According to various embodiments, the insulation sheet is a dielectric material capable of withstanding at least a certain potential, e.g., a 600 V potential or 1000 V potential. In certain embodiments, a PET insulation sheet having a thickness of about 1-10 mils is used. The insulation sheet may be a single sheet or a multi-layer sheet, e.g., with different layers having different material properties or compositions.

The back layer may be a weatherable material capable of protecting the module from external conditions, for example polyvinyl fluoride or other fluoropolymers. In alternative embodiments, the back layer may be another material, and the module may include a weatherable material under the back layer. The back layer may be a single layer or may have multiple layers, e.g., with different layers having different material properties or compositions. If present, the bond between the back layer and another module component may be an adhesive bond, or any other type of bond sufficient to electrically isolate the moisture barrier.

One aspect of the invention relates to solar modules that include a transparent front layer, a multi-layer flexible back sheet; and a plurality of interconnected photovoltaic cells disposed between the transparent front layer and the multi-layer flexible back sheet. The multi-layer flexible back sheet includes an insulation sheet, an electrically isolated moisture barrier, a back layer and a seal; with the insulation sheet disposed between the plurality of photovoltaic cells and the moisture barrier and the moisture barrier disposed between the insulation sheet and the back layer. The seal includes a bond between the insulation sheet and the back layer and extends around the moisture barrier such that the insulation sheet, back layer and seal electrically isolate the moisture barrier.

Another aspect of the invention relates to solar modules including a transparent front layer, an ungrounded moisture barrier flexible back sheet, and a plurality of interconnected photovoltaic cells located between the transparent front layer and the ungrounded moisture barrier flexible back sheet, wherein the ungrounded moisture barrier flexible back sheet has a water vapor transmission rate (WVTR) of no more than about 10⁻² g/m²/day. In certain embodiments, the WVTR no more than about 10⁻³ g/m²/day.

The transparent front layer may be a rigid material, e.g., a glass plate, or it may be flexible material. The photovoltaic cells may be any type of photovoltaic cells, including but not limited to CIS, CIGS, CdTe or silicon photovoltaic cells.

According to various embodiments, the moisture barrier is a pinhole free conductive material, e.g., pinhole free aluminum foil. The moisture barrier is typically thin, e.g., no more than about 50 microns thick, or no more than 25 microns thick. Other thicknesses may be used as appropriate to provide a flexible moisture barrier.

According to various embodiments, the insulation sheet is a dielectric material capable of withstanding at least a certain potential, e.g., a 600 V potential or 1000 V potential. In certain embodiments, a PET insulation sheet having a thickness of about 1-10 mils is used. The insulation sheet may be a single sheet or a multi-layer sheet, with different layers having different material properties or compositions.

The back layer may be a weatherable material capable of protecting the module from external conditions, for example polyvinyl fluoride or other fluoropolymers. In alternative embodiments, the back layer may be another material, and the module may include a weatherable material under the back layer. The back layer may be a single layer or may have multiple layers, e.g., with different layers having different material properties or compositions. The bond between the insulation sheet and back layer may be an adhesive bond, or any other type of bond sufficient to electrically isolate the edge of the moisture barrier.

In certain embodiments, the insulation sheet and/or back layer and the moisture barrier have substantially coextensive end portions along a first direction. For example, in a roll-to-roll process, a module-sized stack, including a moisture barrier as well as insulation sheet and/or back layer may be cut from a web, with the moisture barrier coextensive with the insulation sheet and/or back layer at the cut edges. A coextensive insulation sheet end portion and a moisture barrier end portion may be folded to together form an inwardly curved end portion, with the moisture barrier end portion on the interior of said inwardly curved end portion. In this manner, the edges of moisture barrier are electrically isolated from the rest of the module. In certain embodiments, the seal may include a folded over portion as described.

In certain embodiments, the seal extends at least about 1-2 mm past at least two edges or on all edges of the moisture barrier. In certain embodiments, the width of the seal on at least two edges or on all edges of the moisture barrier is at least about 1-2 mm. In certain embodiments, an edge seal material containing a moisture getter or desiccant material such as a butyl based material, surrounds the photovoltaic cells. The outer perimeter of the moisture barrier may be in between the inner and outer perimeters of the seal material in certain embodiments.

Another aspect of the invention relates to solar modules that include a transparent front layer, a multi-layer flexible back sheet; and a plurality of interconnected photovoltaic cells disposed between the transparent front layer and the multi-layer flexible back sheet. The multi-layer flexible back sheet includes an insulation sheet, an electrically isolated moisture barrier, a back layer and a seal; with the insulation sheet disposed between the plurality of photovoltaic cells and the moisture barrier and the moisture barrier disposed between the insulation sheet and the back layer. The seal includes a bond between the insulation sheet and the back layer and extends around the moisture barrier such that the insulation sheet, back layer and seal electrically isolate the moisture barrier.

Another aspect of the invention relates to solar modules including a transparent front layer, an ungrounded moisture barrier flexible back sheet, and a plurality of interconnected photovoltaic cells located between the transparent front layer and the ungrounded moisture barrier flexible back sheet, wherein the ungrounded moisture barrier flexible back sheet has a water vapor transmission rate (WVTR) of no more than about 10⁻² g/m²/day. In certain embodiments, the WVTR is no more than about 10⁻³ g/m²/day.

The transparent front layer may be a rigid material, e.g., a glass plate, or it may be flexible material. The photovoltaic cells may be any type of photovoltaic cells, including but not limited to CIS, CIGS CdTe or silicon photovoltaic cells.

According to various embodiments, the moisture barrier is a pinhole free conductive material, e.g., pinhole free aluminum foil. The moisture barrier is typically thin, e.g., no more than about 50 microns thick, or no more than 25 microns thick. Other thicknesses may be used as appropriate to provide a flexible moisture barrier.

According to various embodiments, the insulation sheet is a dielectric material capable of withstanding at least a certain potential, e.g., a 600 V potential or 1000 V potential. In certain embodiments, a PET insulation sheet having a thickness of about 1-10 mils is used. The insulation sheet may be a single sheet or a multi-layer sheet, e.g., with different layers having different material properties or compositions.

The back layer may be a weatherable material capable of protecting the module from external conditions, for example polyvinyl fluoride or other fluoropolymers. In alternative embodiments, the back layer may be another material, and the module may include a weatherable material under the back layer. The back layer may be a single layer or may have multiple layers, e.g., with different layers having different material properties or compositions. The bond between the insulation sheet and back layer may be an adhesive bond, or any other type of bond sufficient to electrically isolate the edge of the moisture harrier.

In certain embodiments, the insulation sheet and/or back layer and the moisture barrier have substantially coextensive end portions along a first direction. For example, in a roll-to-roll process, a module-sized stack, including a moisture barrier as well as insulation sheet and/or back layer may be cut from a web, with the moisture barrier coextensive with the insulation sheet and/or back layer at the cut edges. A coextensive insulation sheet end portion and a moisture barrier end portion may be folded to together form an inwardly curved end portion, with the moisture barrier end portion on the interior of said inwardly curved end portion. In this manner, the edges of moisture barrier are electrically isolated from the rest of the module. In certain embodiments, the seal may include a folded over portion as described.

In certain embodiments, the seal extends at least about 1-2 mm past at least two edges or on all edges of the moisture barrier. In certain embodiments, the width of the seal on at least two edges or on all edges of the moisture barrier is at least about 1-2 mm. In certain embodiments, an edge seal material containing a moisture getter or desiccant material such as a butyl based material, surrounds the photovoltaic cells. The outer perimeter of the moisture barrier may be in between the inner and outer perimeters of the seal material in certain embodiments.

Also provided are flexible multi-layer back sheets and methods of fabricating the same, as well as pre- and post-laminate back sheet and solar module stack assemblies. These and other aspects of the invention are described further below with reference to the figures.

### BRIEF DESCRIPTION OF THE DRAWINGS

FIG. 1 is a cross-sectional view of certain components of a solar module.

FIG. 2 is a cross-sectional view of a flexible back sheet according to certain embodiments.

FIGS. 3A and 4A are cross-sectional views of solar modules having metalized back sheets according to various embodiments.

FIGS. 3B and 4B are cross-sectional views of solar modules including two distinct seals, one to isolate photovoltaic cells and one to isolate a moisture barrier.

FIG. 5 depicts 1) a plan view according to certain embodiments of a solar cell area of a solar module and moisture getter/desiccant material surrounding the solar cell area, 2) a plan view according to certain embodiments of a metallic moisture barrier of a solar module and a back layer surrounding the metallic moisture barrier, and 3) a plan view of a solar cell area and surrounding moisture getter overlying a metallic moisture barrier and back layer, also according to certain embodiments.

FIG. 6 depicts certain operations in roll-to-roll processes of forming multi-layer back sheets according to various embodiments.

FIG. 7 depicts various views of a cut laminate, stack including a moisture barrier and overlying and underlying polymer layers according to certain embodiments.

FIG. 8 depicts certain operations in roll-to-roll processes of forming multi-layer back sheets according to various embodiments

FIG. 9A depicts a plan view of a solar module array including electrically interconnected solar modules according to certain embodiments.

FIG. 9B depicts a cross-sectional view of an electrical connector that may be used to connect photovoltaic cells of a solar module to a grid, solar module array, or other external connection point according to certain embodiments.

### DETAILED DESCRIPTION

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. In the following description, numerous specific details are set forth in order to provide a thorough understanding of the present invention. The present invention may be practiced without some or all of these specific details. In other instances, well known mechanical apparatuses and/or process operations have not been described in detail in order not to unnecessarily obscure the present invention.

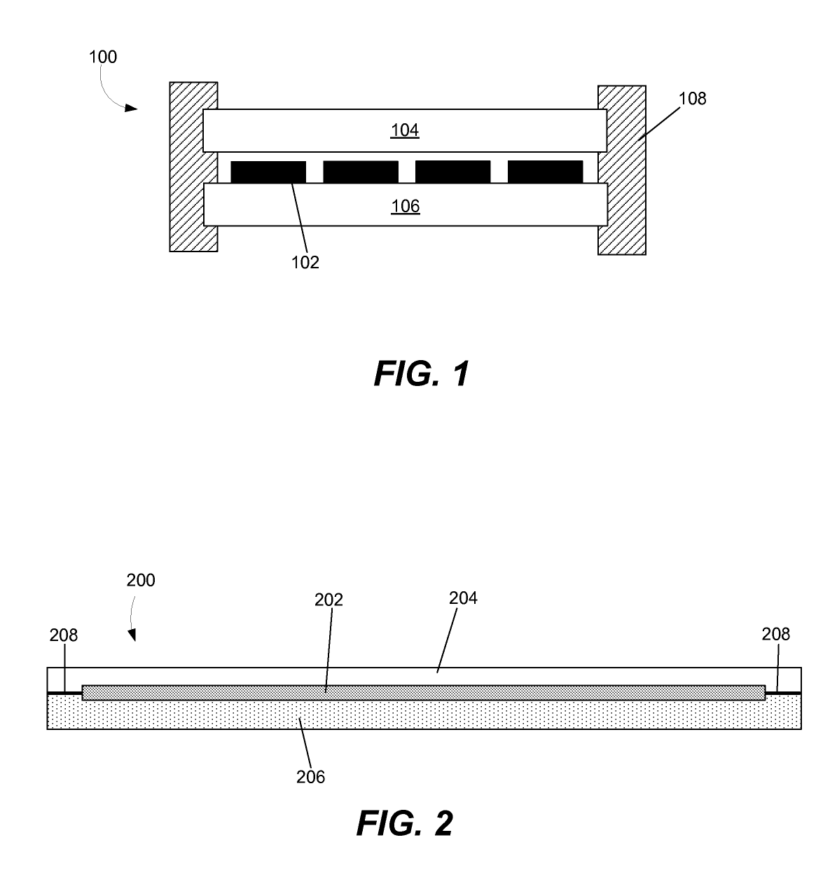

Embodiments of the present invention relate to encapsulating solar modules for environmental protection and mechanical support. FIG. 1 shows a not-to-scale cross-sectional view of certain components of a solar module 100, including interconnected solar cells 102 and front and back encapsulating layers 104 and 106, respectively. Front and back encapsulating layers 104 and 106 protect interconnected solar cells 102 and other module components from environmental conditions. In certain modules, a frame 108 surrounds the rest of the module for mechanical support.

Front and back encapsulating layers 104 and 106 can contribute significantly to the weight and transportation costs of a module. Rigid materials such as glass sheets, for example, provide good protection against environmental conditions but can add on the order of $2/sheet in transportation costs. While flexible materials such as aluminum foil are lighter and cheaper than glass, they present their own costs and issues. In particular, conventional metalized back sheets require grounding the metal in the back sheet or a grounded metal frame surrounding the module to prevent electrical shorting. Grounding a module, e.g., via a conductive frame also presents a major cost: the frame, conductors to ground, and installation costs of a grounded module are significant and present barriers to the competitive pricing of solar energy generation.

Provided herein are flexible encapsulating materials that do not require grounding or framing. The materials are considerably lighter and easier to handle than rigid encapsulation materials, and do not require the attendant issues of grounding and framing that conventional metalized encapsulation layers do. In certain embodiments, a flexible metallic back sheet is provided. Unlike current metalized back sheets for moisture impermeable solar module encapsulation, the metalized back sheets described herein do not require grounding to meet UL standards, and may be ungrounded in certain embodiments. Section 690.43 of the 2005 National Electrical Code (NEC) requires that: “Exposed non-current-carrying metal parts of module frames, equipment, and conductor enclosures shall be grounded in accordance with 250.134 or 250.136(A) regardless of voltage.” Because embodiments of the invention do not have exposed moisture barriers, or in certain embodiments, any exposed metal parts, they do not require grounding to be in compliance with the 2005 version of the US NEC. In particular embodiments, the solar modules or back sheets described herein meet the wet leakage current and/or high potential standards as defined in UL 1703. Article 690 of the 2005 NEC and UL 1703, edition 3, as revised April 2008, are incorporated by reference herein.

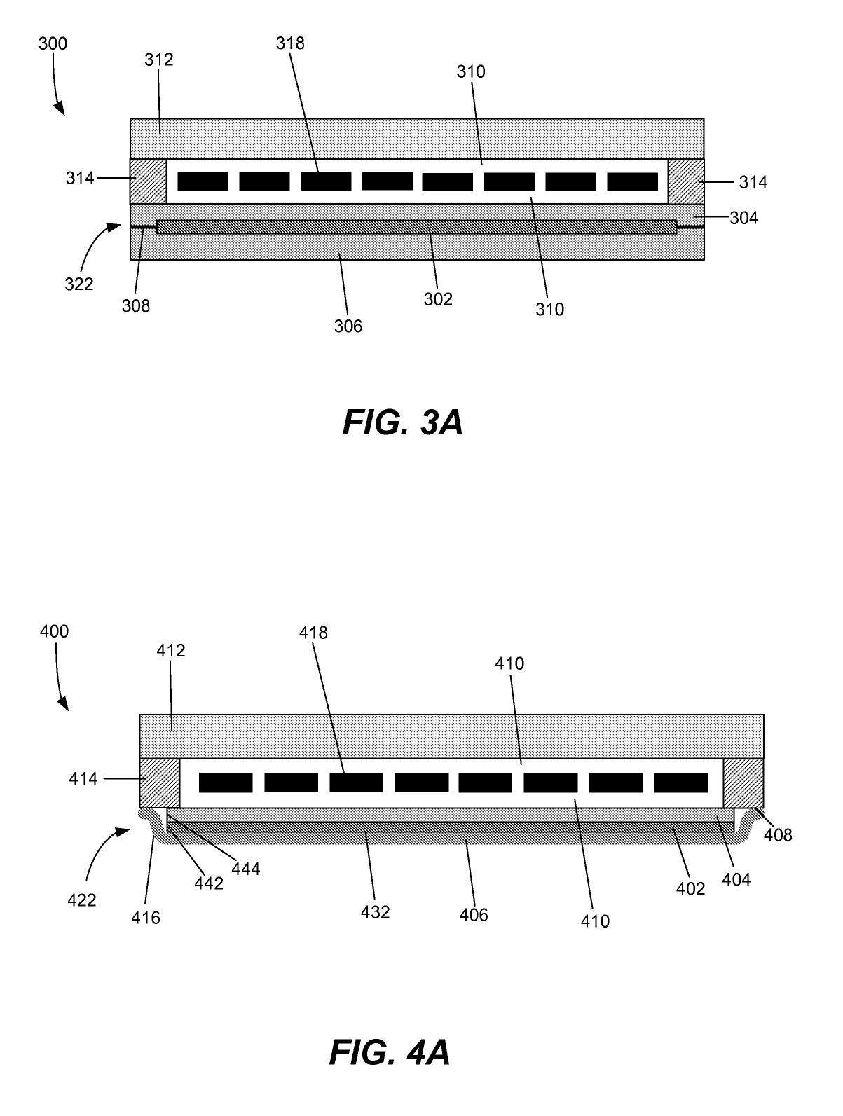

FIG. 2 is a not-to-scale cross-sectional view of a flexible back sheet 200 according to certain embodiments. Back sheet 200 includes a flexible moisture barrier 202 sandwiched between an insulation sheet 204 and a back layer 206. A seal 208 extends around the moisture barrier. Insulation sheet 204, back layer 206 and seal 208 together electrically isolate the moisture barrier 202 to prevent shorting between the solar cells in the assembled module and the moisture barrier 202. As is described further below with respect to FIG. 4A, in certain embodiments, the back layer extends towards the front layer to cover the edges of the moisture barrier. In these embodiments, the back layer may also cover the edges of the insulation sheet.

Moisture barrier 202 may be any material that is flexible and moisture impermeable. Moisture impermeability may be defined by the water vapor transmission rate (WVTR), the steady state rate at which water vapor permeates through a film at specified conditions of temperature and relative humidity. According to various embodiments, the moisture barrier has a WVTR of no more than 10⁻² g/m²/day at 38° C. and 100% relative humidity. In certain embodiments, the moisture barrier has a WVTR of no more than 10⁻³ g/m²/day at 38° C. and 100% relative humidity.

The moisture barrier may be a pinhole-free metallic material, including, but not limited to pinhole-free aluminum foil. In addition to aluminum or alloys thereof, metallic moisture barriers may be copper, palladium, titanium, gold, silver, iron, molybdenum, stainless steel, steel, zinc, alloys thereof such as brass, or other combinations thereof. In certain embodiments, the moisture barrier may be a metallic or other conductive material in combination with another material. The moisture barrier should be thick enough to be pinhole-free, or to meet the desired WVTR. This varies according to the particular metal used. In one example, aluminum foil as thin as about 17 microns is used. In another example, pinhole-free aluminum foil as thin as about 25 microns, or about 50 microns is used. In certain embodiments, moisture barriers between about 5 and 500 microns may be used, though other thicknesses may be used as well.

In certain embodiments, insulation sheet 204 is sufficient to withstand a high electrical potential between a conductive moisture barrier 202 and the solar cells (not shown) to prevent arcing or shorting. The voltage withstand of the sheet is a function of the material properties of the insulation sheet material as well as the thickness of the sheet. In certain examples, thickness ranges from about 1 to 10 mils or higher, though other thicknesses may be used as appropriate. According to various embodiments, the voltage withstand of the insulation sheet is at least about 500 V, at least about 600 V, at least about 700 V, at least about 800 V, at least about 900 V, at least about 1000 V, at least about 1500 V, or at least about 2000 V. In certain embodiments, the insulation material is or contains a thermoplastic material. Non-limiting examples of insulation materials include thermal polymer olefins (TPO) and non-olefin thermoplastic polymers, including polyethylene, polypropylene, polybutylene, polyethylene terephthalate (PET), polybutylene terephthalate (PBT), polystyrene, polycarbonates, ethylene-vinyl acetate (EVA), fluoropolymers, acrylics, including poly(methyl methacrylate), or silicones, as well as multilayer laminates and co-extrusions, such as PET/EVA laminates or co-extrusions. In one example, the insulation sheet is PET. In other examples, the insulation sheet is a nylon, acylonitrile butadiene styrene ABS), polybutylene terephtalate (PBT), (polycarbonate (PC), PPS (polyphenylene sulfide (PPS), or potyphenylene oxide (PPO). Other suitable electrically insulating materials may be used, e.g., thin ceramic materials. Filled materials may also be used.

Back layer 206 may be a weatherable material that protects the cells and other module components from moisture, UV exposure, extreme temperatures, etc. The back layer may be a fluoropolymer, including but not limited to polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE). Other weatherable materials may be used in addition to or instead of a fluoropolymer, including silicone polyesters, chlorine-containing materials such as polyvinyl chloride (PVC), plastisols and acrylics. In certain embodiments, any material that meets UL 1703 requirements (incorporated by reference above) is used. In one example, the back layer is PVF. In certain examples, thickness range from about 1 to about 4 mils, although other thicknesses may be used as appropriate.

Seal 208 includes a bond between back layer 206 and insulation sheet 204 and is effective to prevent any electrical contact between the moisture barrier and the solar cells or any other component of the module at the edge of moisture barrier 202. It is typically a permanent or irreversible seal and prevents peeling at the edges that would expose the edge of moisture barrier 202. According to various embodiments, the seal is at least 0.5 mm, 1 mm or 2 mm wide and extends around the edge of the moisture barrier. The bond between back layer 206 and insulation sheet 204 may be an adhesive bonding, a fusion bonding, a welding, a solder bond, or a mechanical fastening. As used herein, the term “permanent seal” refers to a seal that has a resistance to rupture greater than a frangible seal. As used herein, “irreversible seal” refers to seal that is unbreakable by exposure to atmospheric heat and weather conditions, and generally must be deliberately tampered with to be broken. In certain embodiments, the seal includes covalent bonding, e.g., between an adhesive and the back layer and/or insulation sheet, or between the insulation sheet and back layer, etc.

If an adhesive material is used, it may be a thermoplastic adhesive, a liquid adhesive, a curable adhesive, or any other type of adhesive that creates an irreversible seal, is resistant to peeling and has good moisture resistance. Thermoplastic adhesives that may be used include acrylics, silicone resins, polyamines and polyurethanes. In certain embodiments, the adhesive may also be used to adhere the insulation sheet and back layer to the moisture barrier. In certain, embodiments, one of the layers may be formed by extrusion coating or casting, e.g., on a chemically primed surface. For example, moisture barrier 202 may be adhered to insulation sheet 204. Insulation sheet 204 or (insulation sheet 204 and moisture barrier 202) may then be chemically primed and back layer 206 formed by extrusion coating or casting onto the chemically primed surface.

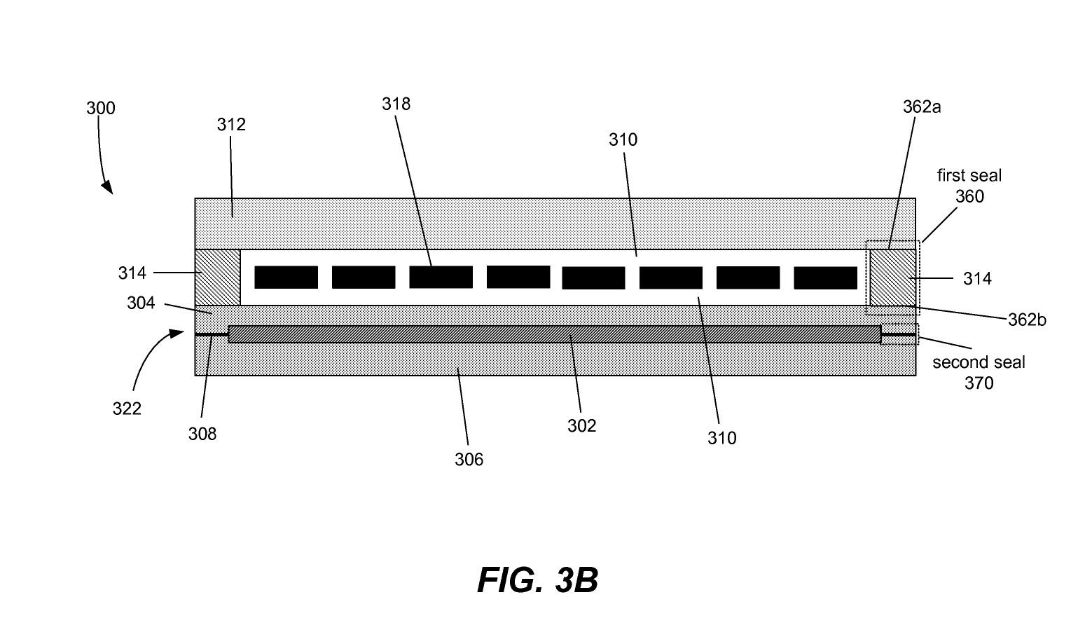

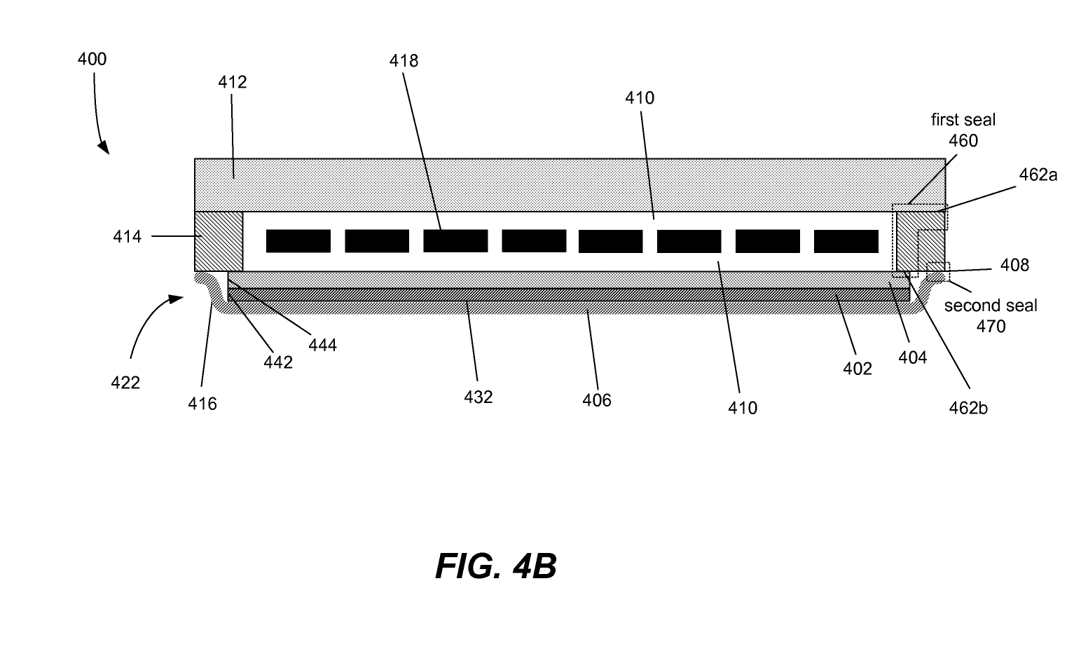

FIG. 3A shows an example of solar module 300 having a metalized back sheet 322 as described above with reference to FIG. 2. For the purposes of illustration, the schematic is not drawn to scale. Solar cells 318 may be any type of solar cells, including but not limited to, semiconductor-based solar cells including microcrystalline or amorphous silicon, cadmium telluride, copper indium gallium selenide or copper indium selenide, dye-sensitized solar cells, and organic polymer solar cells.

Solar cells 318 are encapsulated by a material 310 that protects the solar cells and that may include one or more layers of a thermoplastic material, e.g., an acrylic or silicone material. A material 314 surrounds solar cells 318. The material 314 may be an organic or inorganic material that has a low inherent WVTR (typically less than 1-2 g/m²/day) and, in certain embodiments may absorb moisture, prevents its incursion through and along edges of material 310. In one example, a butyl-rubber containing moisture getter or desiccant is used. The encapsulated cells 318 are protected by a transparent front layer 312 and back sheet 322, including weatherable back layer 306, insulation sheet 304, moisture barrier 302 and seal 308.

In the figure, moisture barrier material 302 is disposed under solar cells 318, but extends at least a small distance past solar cells 318, such that it partially underlies material 314. In certain embodiments, the outer perimeter of the moisture barrier 302 is located between the inner and outer perimeters of the material 314.

FIG. 4A depicts a photovoltaic module 400 including a multi-layer back sheet 422 according to another embodiment. For the purposes of illustration, the schematic is not drawn to scale. As described above, solar cells 418 are encapsulated by a material 410. A material 414 surrounds the solar cells to provide an edge seal. The encapsulated cells 418 are protected by a transparent front layer 412 and multi-layer back sheet 422. Multi-layer back sheet 422 includes moisture barrier 402 disposed between insulation sheet 404 and back layer 406. Back layer 406 has planar dimensions larger than those of the moisture barrier 402 and insulation sheet 404. The perimeter portion 416 of back layer 406 extends toward front layer 412 so that back layer 406 encloses the perimeter edge 442 of moisture barrier 402 as well as surface 432 of moisture barrier 402. In the figure, the perimeter portion 416 of back layer 406 covers the perimeter edge 444 of insulation sheet 404 as well. The back layer 406 may or may not physically contact each of the edges 442 and 444 of the moisture barrier and insulation sheet, respectively.

In this example, perimeter portion 416 of back layer 406 is bonded to edge material 414 to form a seal at 408. Depending on the particular arrangement of the module components, the perimeter portion 416 of back layer 406 may be sealed to any suitable materials or layers that are disposed on the opposite side of moisture barrier 402 as the main portion of back layer 406. For example, the back layer may form a seal with an insulation sheet, an encapsulant material such as material 410, a transparent front layer 412, or any other suitable module component, or combination of these. According to various embodiments, the seal is at least 0.5 mm, 1 mm or 2 mm wide. It may extend around the module to fully isolate the moisture barrier.

Prior to being folded or bent toward the photovoltaic cells, the back layer 406 may have dimensions slightly larger than the front layer 412, i.e., to account for the perimeter portion 416 that is bent toward the edge material. According to various embodiments, the back layer extends up to 10 mm past each edge of the moisture barrier and/or insulation sheet. In certain embodiments, the insulation sheet and moisture barrier are about equally sized. In other embodiments, the insulation sheet may be larger than the moisture barrier.

As indicated above, in certain embodiments, the module includes a permanent and/or irreversible seal that includes bonding between the back layer and the edge material or other module component to which the back layer is sealed. This may be an adhesive bonding, a fusion bonding, a welding, a solder bond, or a mechanical fastening. In certain embodiments, the seal includes covalent bonding, e.g., between an adhesive and the back layer and/or edge material, or between the back layer and edge material, etc. Moisture barrier 402 is electrically isolated by insulation sheet 404 and sealed back layer 406.

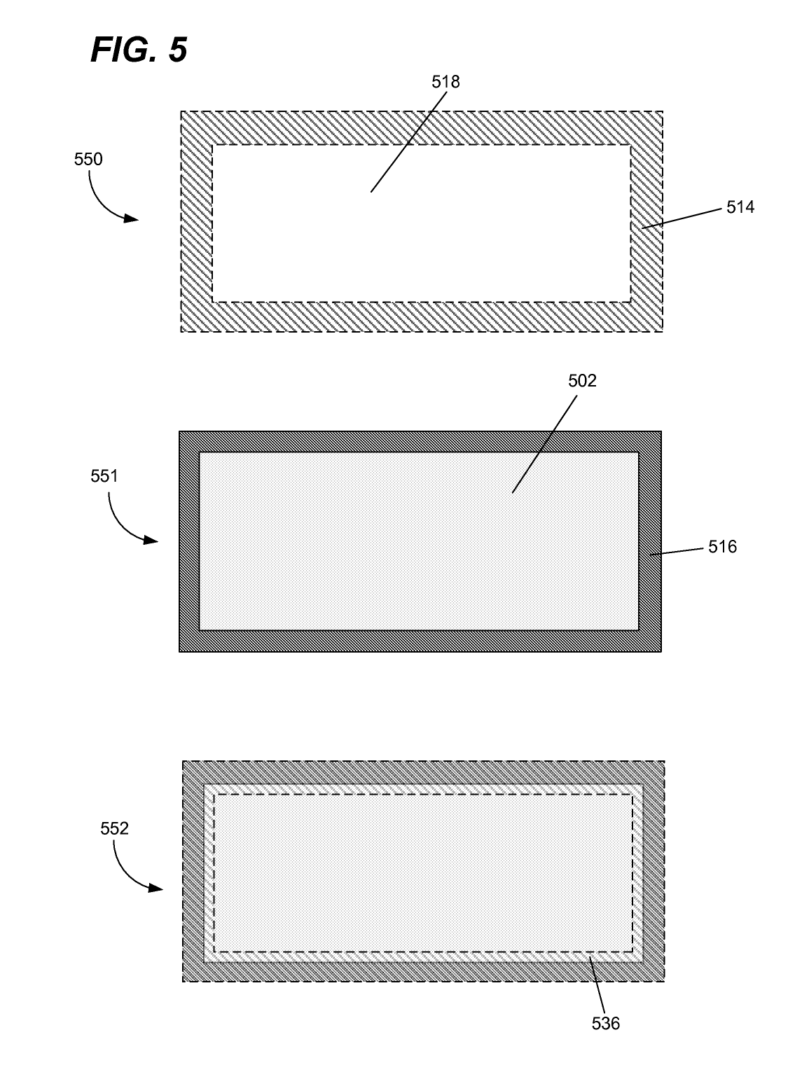

In certain embodiments, the moisture barrier overlaps with an edge seal material surrounding the solar cells in a plane vertical to the module. FIG. 5 shows a plan view 550 of solar cell area 518 and material 514 surrounding solar cell area 518 according to certain embodiments. Also shown is a view 551 of a metallic moisture barrier 502 overlying a back layer, the perimeter portion 516 of which is shown. (For the purpose of illustration, other layers, such as an insulation sheet and encapsulation material, etc. are not depicted.)

Plan view 552 shows the solar cell area 518 and surrounding material 514 (as depicted in view 550) overlying the metallic moisture barrier 502 and the back layer including the perimeter portion 516 (as depicted in view 551). Material 514 and metallic moisture barrier 502 overlap in region 536. This provides moisture protection over the entire solar cell area 518. All or a portion of the back layer that extends past the moisture barrier (perimeter area 516) may contact and/or be sealed to all or a portion of another module component, e.g., to an insulation sheet (as depicted in FIG. 3A), edge material 514 (as depicted in FIG. 4A), or other appropriate layer or material. In certain embodiments, the perimeter portion of the back layer may contact or be sealed to multiple other layers or materials in the module.

Conventional back sheets that incorporate a metallic sheet, such as Tedlar®/Al foil/PET back sheets, require grounding the aluminum foil in the back sheet or a grounded metal frame surrounding the module to meet UL and other safety requirements. This is due to the exposure or possible exposure of the aluminum foil at the cut edge. According to various embodiments, the moisture barriers described herein are ungrounded. The overlying and underlying polymers layers (e.g., PET insulation sheet and PVF weatherable hack layer) together with the seal surrounding the moisture barrier electrically isolate the moisture barrier, obviating the need to ground the moisture barrier. Because the electrically isolated moisture barriers described herein do not need to be grounded, mechanical support considerations are decoupled from electrical considerations. Thus, according to various embodiments, the solar cell modules described herein included frameless as well as framed modules. In certain embodiments, the unframed modules may be configured to be attached an array frame or other support structure at an installation site.

Examples of multi-layer flexible back sheets and solar modules including these back sheets are described above. Another aspect of the invention provides modules that include two distinct seals: one seal that isolates the photovoltaic cells and another seal that isolates the moisture barrier. By providing two such seals, shorting between the moisture barrier and photovoltaic cells or connections thereto is avoided. Each of the two seals includes a permanent and/or irreversible connection between two layers or module components. In certain embodiments, the seal may include a sealing material, e.g., an adhesive, a desiccant, or other sealing material between the module components. In certain embodiments, the two layers or components connected together directly.

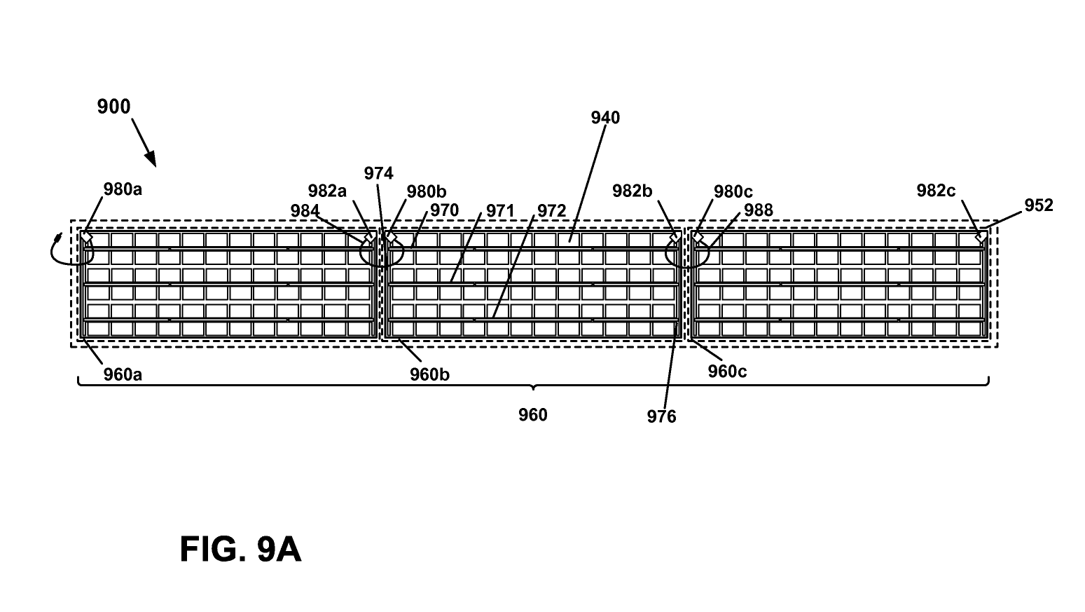

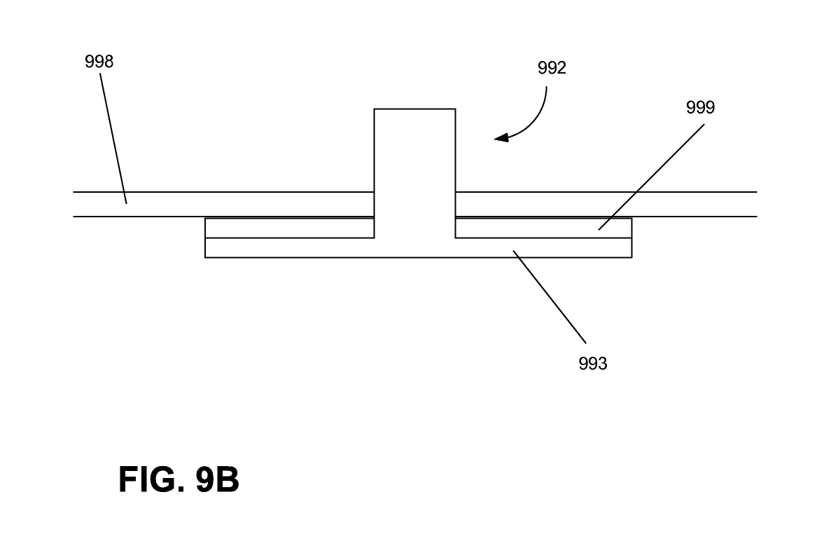

FIG. 3B, for example, illustrates placement of seals in the module depicted in FIG. 3A. A first seal is shown within box 360 and includes sealing material 314, an interface 362a between sealing material 314 and front sheet 312, and an interface 362b between sealing material 314 and back sheet 322 (in this embodiment, more specifically between sealing material 314 and insulation sheet 304). Interfaces 362a and 362b may include bonds, including adhesive bonds, covalent bonds, etc., or other connections as described above. There may be additional adhesive materials between sealing material 314 and either or both of front sheet 312 and back sheet 322. Front sheet 312, back sheet 322 and the seal depicted in box 360 physically isolate photovoltaic cells 318, preventing any electrical connection outside of the area defined by these components other than via a safe electrical connector (not shown) to the module exterior. In certain embodiments, the sole electrical connection to photovoltaic cells in module 300 is one or more connectors extending from busbars or other points of electric contact to the cells that are within the module 300 to the exterior of the module. For example, one or more connectors may extend from a module through front sheet 312. Examples of such connectors are described further with respect to FIGS. 9A and 9B, below. As discussed above, the seal within box 360 prevents moisture from penetrating to the photovoltaic cells 318.

In certain embodiments, the seal surrounding the photovoltaic cells includes a desiccant-loaded low moisture vapor transmission polymer. Such polymers may be characterized by the time to moisture breakthrough. In certain embodiments, there is no moisture breakthrough for more than a thousand hours and more particularly more than two thousand hours.

A second seal 308 is depicted with box 370. Here, the seal 308 includes the connection between insulation sheet 304 and back layer 306. In the depicted embodiment, the seal includes a bond between these two layers. In other embodiments, another material may be present between the layers. With insulation sheet 304 and back layer 306, seal 308 completely electrically isolates moisture barrier 302. The seals depicted within boxes 360 and 370 are physically separate, having no common interface.

In another example, FIG. 4B illustrates seal placement in the module depicted in FIG. 4A. A first seal is shown within area 460 and includes sealing material 414, an interface 462a between sealing material 414 and front sheet 412, and an interface 462b between sealing material 414 and back sheet 422 (in this embodiment, more specifically between sealing material 414 and insulation sheet 404). This is similar to the seal depicted in FIG. 3B, except that interface 462b is smaller to accommodate the second seal, which in this case includes a separate interface to sealing material 414. Along with front sheet 412 and insulation sheet 404, the seal within area 460 physically isolates photovoltaic cells 418 and related wiring. This allows the only electrical connection to cells 418 to be via one or more connectors that provide safe connection to the exterior of the module, such as depicted in FIGS. 9A and 9B. A second seal 408 is depicted within box 470. Here, the seal 408 includes the connection between sealing material 414 and back layer 406. In the depicted embodiment, the seal includes a bond between these two layers. In other embodiments, another material may be present between the layers. With insulation sheet 404, sealing material 414, and back layer 406, seal 408 completely electrically isolates moisture barrier 402.

Separate seals for isolating the photovoltaic cells and moisture barrier prevents shorting between the photovoltaic cells and the moisture barrier. Even in the event of a seal breach (e.g., because of physical disruption), shorting does not occur, with the other seal intact. The photovoltaic cell seals and moisture barrier seals described above with reference to FIGS. 3A, 3B, 4A and 4B, are examples of such seals. In other embodiments, one or more of the distinct seals may take different forms in terms of which module layers or components are sealed together and how these layers or other components are sealed together, e.g., including a separate sealing material or not, including an adhesive bonding or not, including covalent bonding or not, etc. In many embodiments, the photovoltaic modules including two seals include multi-layer flexible back sheets, e.g., as described above with reference to FIGS. 3A and 4A. However, these photovoltaic modules are not so limited and may include any flexible back sheets including a moisture barrier isolated by a seal.

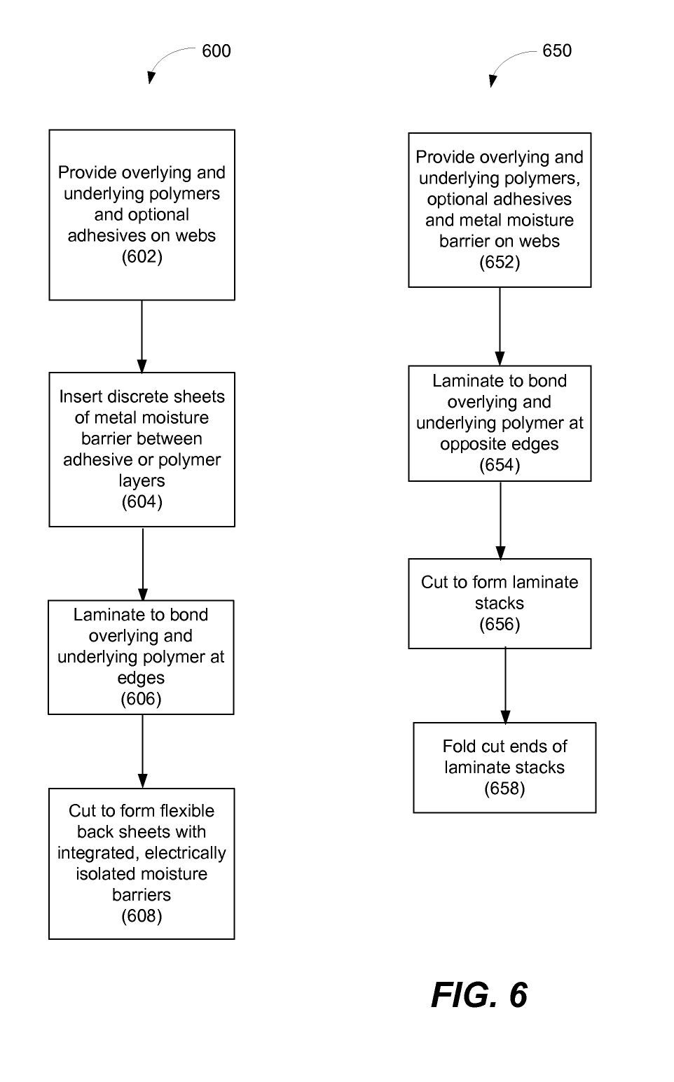

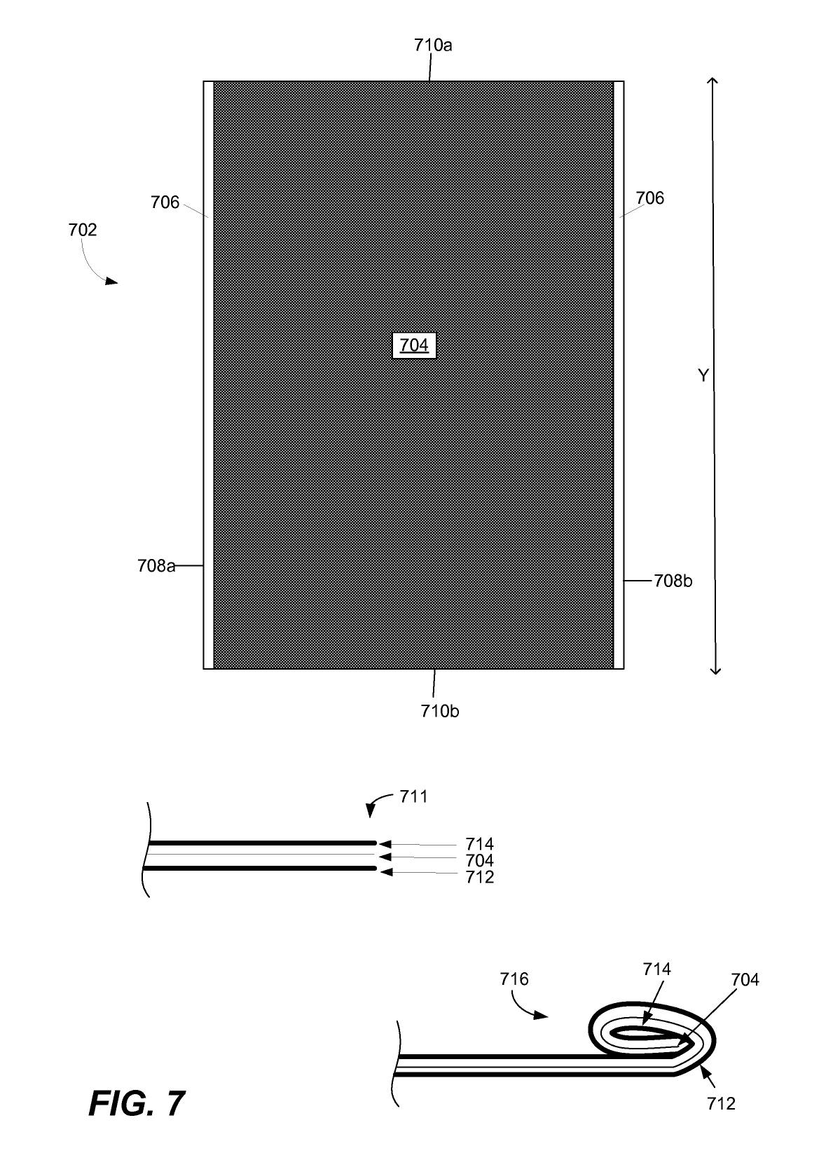

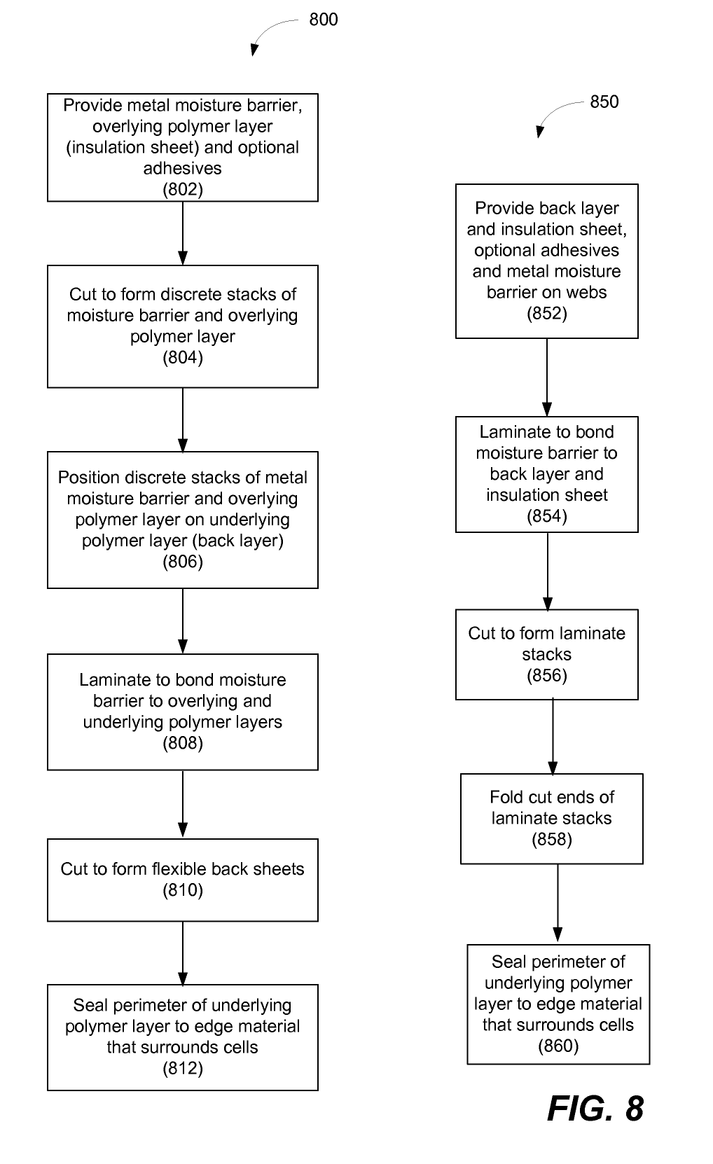

Also provided are processes of fabricating the multi-layer back sheets described herein. FIGS. 6-8 depicts operations in roll-to-roll processes of forming multi-layer back sheets according to various embodiments. FIGS. 6 and 7 depict operations in forming multi-layer back sheets as depicted in FIG. 3A and FIG. 8 depict operations in forming multi-layer back sheets as depicted in FIG. 4A.

Turning first to FIG. 6, in process 600, discrete sheets of metal foil, typically having dimensions less than the underlying back layer and overlying insulation sheet are inserted into a pre-laminate stack including a polymeric insulation sheet and back layer material. The process begins at an operation 602, in which insulation sheet and back layer polymers and, if used, thermoplastic adhesives are provided on webs. For example, webs of PET, adhesive and PVF may be provided to assemble a PET/adhesive/adhesive/PVT pre-laminate stack. In an operation 604, discrete sheets of a metallic moisture barrier are inserted between the polymer sheets. For example, a sheet of aluminum foil is inserted between adhesive sheets to form a PET/adhesive/Al foil/adhesive/PVF pre-laminate stack assembly. The aluminum foil or other moisture barrier may be inserted before or after transverse cuts are made to form module-sized stacks. The pre-laminate stack assembly including a moisture barrier is then laminated in an operation 606, forming a seal around the entire perimeter of the moisture barrier. If still on a roll, the laminate stack may be cut as appropriate to define a module back sheet in an operation 608. The laminate stack may then be assembled with the solar cells, front layer and other module components to complete the module. One of skill in the art will understand that the order of various cutting, laminating and module assembly operations may vary. Also, another type of bonding (welding, fusing, etc.) may be performed form the seal surrounding the moisture barrier.

In process 650, rather than inserting discrete sheets, the aluminum or other moisture barrier material is also provided as a web. The process begins in an operation 652 in which the polymer insulation sheet, adhesives (is used), backing layer and moisture barrier are provided on webs to form a pre-laminate stack assembly, e.g., insulation sheet/adhesive/moisture barrier/adhesive/back layer. In certain embodiments, the width of the moisture barrier web is less than the other webs to allow for formation of a seal. The pre-laminate stack assembly is laminated in an operation 654. The laminate stack is cut in an operation 656 to form module-sized laminate stacks. In certain embodiments, the resulting module-sized stack includes a moisture barrier material extending to the cut edges. This is depicted in FIG. 7, which shows a top view of laminate stack 702, including moisture barrier 704, uncut edges 708a and 708b, cut edges 710a and 710b, and a seal 706 along opposing uncut edges 708a and 708b of the laminate stack. Seal 706 includes bonded-together insulation sheet and backing layer polymeric layers. The moisture barrier 704 and the overlying and underlying polymer layers are coextensive along the length of module-sized stack (direction “Y” in the figure). A side view of a cut edge 711 is shown, with polymer layers 712 and 714 and moisture barrier 704. (Adhesive layers are not depicted for the sake of illustration). Returning to FIG. 6, to electrically isolate the moisture barrier, the cut edges are folded in an operation 658. An example of such as fold is depicted at 716 in FIG. 7, with polymer layers 712 and 714 and moisture barrier 704 curved inward together, such that the edge of moisture barrier 704 is fully isolated by one or more of layers 712 and 714. An additional sealing operation may then be performed, e.g., by applying heat, pressure and or adhesive to the fold. The fold may include one or more inward curved portions, including bent or angled portions. In the example shown in FIG. 7, the edge is folded twice to form two inward curved portions, fully isolating the edge of the moisture barrier along the cut sides. The fold may be considered part of the seal that extends around the solar module.

FIG. 8 depicts operations in roll-to-roll processes of forming a multi-layer back sheet such as that depicted in FIG. 4A. In process 800, the insulation sheet and metal foil are cut together, to form discrete insulation sheet/metal barrier stacks that sized and positioned on the back layer material such that the perimeter of the back layer extends around the metal barrier and insulation sheet. The process begins at an operation 802, in which insulation sheet and moisture barrier materials are provided. If used, thermoplastic or other adhesives may also be provided. The materials may be provided on webs or in other appropriate form. In an operation 804, the overlying polymer and moisture barrier material are cut to form discrete stacks of insulation sheet and moisture barrier material in their desired size. In embodiments in which the insulation sheet and moisture barrier are of approximately the same size, the insulation sheet and moisture barrier may be cut simultaneously. Also, in certain embodiments, the insulation sheet material and moisture barrier material may be received already appropriately sized without needing to be cut. Once an appropriately-sized insulation sheet and moisture barrier stack is formed, it is then positioned on back layer material in an operation 806. Adhesive layers may also be part of the stack or otherwise appropriately placed. The back layer material may be provided on a web. A lamination operation may be performed to bond the layers together in an operation 808. If still on a roll, the back layer may be cut as appropriate to define a module back sheet in an operation 810. At this point, the insulation sheet covers one surface of the moisture barrier with the back layer covering the opposite surface of the moisture barrier. The perimeter of the back layer may be bent or otherwise extended upward to cover the edge of moisture barrier, or this may occur during further processing when the back sheet is assembled with the rest of the module components. For example, the back layer/moisture barrier/insulation sheet stack may then be assembled with the solar cells, front layer and other module components to complete the module. In doing so, the perimeter of the back layer may be sealed in an operation 812 to another module component, such as the edge seal material that surrounds the solar cells. One of skill in the art will understand that the order of various cutting, laminating and module assembly operations may vary.

In a process 850, rather than positioning discrete stacks of insulation sheet and moisture barrier material on the back layer, the flexible back sheets may be assembled using a roll-to-roll process. The process begins in an operation 852 in which the polymer insulation sheet, adhesives (is used), backing layer and moisture barrier are provided on webs to form a pre-laminate stack assembly, e.g., insulation sheet/adhesive/moisture barrier/adhesive/back layer. In certain embodiments, the width of the back layer web is greater than the insulation sheet and moisture barrier webs to allow the perimeter of the hack layer to cover the edges of those layers. The pre-laminate stack assembly is laminated in an operation 854. The laminate stack is cut in an operation 856 to form module-sized laminate stacks. In this case, the laminate stacks may look like the laminate stack shown at view 702 in FIG. 7, with 706 representing the width of the back layer material that extends past the insulation sheet and moisture barrier on the uncut edges. As depicted at view 711 in FIG. 7, the resulting module-sized stack includes a moisture barrier material extending to the cut edges. To electrically isolate the moisture barrier, the cut edges are folded in an operation 858, as depicted at 716 in FIG. 7. The unfolded edges of the back layer may then be sealed to another module component as described above in an operation 860. In certain embodiments, the folded edges may be similarly sealed.

As indicated above, the flexible back sheets and modules described herein include electrically isolated moisture barriers. In certain embodiments, the photovoltaic cells are electrically connected to the exterior of the module only by one or more connectors that safely connect to the exterior. An example is shown in FIG. 9A, which shows a plan view 900 of a solar module array 952 including a plurality 960 of solar modules 960a, 960b and 960c. Each module includes a set of interconnected solar cells 940. The cells may be any type of photovoltaic cells, including but not limited to CIS, CIGS, CdTe or silicon photovoltaic cells. The plurality 960 of solar-cell modules 960a, 960b and 960c are interconnected via external connector assemblies mounted on the modules and connected to in-laminate-diode assemblies. For example, solar-cell module 960b includes a first in-laminate-diode assembly 970, a second in-laminate-diode assembly 971 and a third in-laminate-diode assembly 972; solar module 960b also includes a first busbar 974 and a terminating busbar 976 each electrically coupled with the first, second and third in-laminate-diode assemblies 970, 971 and 972. The solar module 960b further includes first and second electrical connector assemblies 980b and 982b, mounted on the glass or other protective structure of the module. The first and second electrical connector assemblies 980b and 982b are configured to enable current collection from interconnected solar cells of the module 960b and to allow interconnection with at least one other external device, in this case module 960a for electrical connector assembly 980b, and module 960c for electrical connector assembly 982b. Solar module 960a similarly includes external electrical connector assemblies 980a and 982a and solar module 960c similarly includes external electrical connector assemblies 980c and 982c. Solar modules 960a and 960b are intercoupled with interconnector 984 and solar modules 960b and 960c are intercoupled with interconnector 988. FIG. 9A shows an example of electrical connectors; the placement of the electrical connector assemblies may be varied appropriate on the module—at its center, edge, etc. One or more such connectors may be used per module. Aspects of the invention include such solar module arrays including modules having the flexible back sheets including electrically isolated moisture barriers described above.

FIG. 9B shows a cross-sectional view of an electrical connector assembly for a photovoltaic module 995, that may be used to connect the photovoltaic modules according to certain embodiments. A conductive stud assembly 992 includes a base portion or flange 993. A seal 999 is disposed between base portion 993 and front sheet 998 of the photovoltaic module 995. A finger-safe sheath or housing (not shown) covers the conductive stud in use preventing unwanted contact to the cells. Seal 999 between the base portion 993 of the conductive stud assembly 992 and the front sheet 998 of the photovoltaic module 995 provides additional protection to internal portions of the photovoltaic module in adverse weather conditions. The seal may comprise a material that acts as a desiccant to prevent water from entering the interior of the module, for example a zeolite. Examples of seal materials that may be used include butyl rubber and silicone. The seal may also be relatively thick compared to the thickness of the base portion 993 of the stud assembly 992. Example thickness of the seal range from about 0.5 to 5 mm. FIG. 9B shows an example of an electrical connector, which may take other shapes and forms, including horizontal pins, etc.

### Other Embodiments

According to various embodiment, the flexible back sheet may include one or more additional layers. For example, in certain embodiments, additional layers may be between the moisture barrier layer and a weatherable material and/or between the moisture barrier layer and an insulation layer. The seal may include a bond between any of the layers, so long as a layer overlying the moisture barrier is bonded to an underlying barrier such to prevent any electrical connection to the edge of the moisture barrier.

While the description above refers chiefly to metallic moisture barriers, other types of flexible moisture barriers are within the scope of the invention, including moisture barriers made of non-metallic conductive materials, semiconductor materials, etc. As described above, in certain embodiments, the back sheets and methods described herein find particular application with conductive moisture barriers.

In addition to the specific examples of polymeric materials that may be used for the insulation sheet, back layer, adhesives, etc., examples of materials that may be used as appropriate for one of these layers or for other layers in the module include, silicone, silicone gel, epoxy, RTV silicone rubber, polydimethyl siloxane (PDMS), polyvinyl butyral (PVB), polycarbonates, acrylics, urethanes including thermoplastic polyurethanes (TPU), poly(vinyl acetal), polyolefin block elastomers, ethylene acrylate ester copolymers, acid copolymers, silicone elastomers, epoxy resins, polyolefin block elastomers, ethylene acrylate ester copolymers, rubber, thermoplastic elastomers, other materials with similar material properties, and mixtures thereof.

Although the foregoing invention has been described in some detail for purposes of clarity of understanding, it will be apparent that certain changes and modifications may be practiced within the scope of the invention. It should be noted that there are many alternative ways of implementing both the processes and apparatuses of the present invention. Accordingly, the present embodiments are to be considered as illustrative and not restrictive, and the invention is not to be limited to the details given herein.

1. A photovoltaic module comprising:
a transparent front layer;
a flexible back sheet comprising an electrically isolated moisture barrier;
a plurality of interconnected photovoltaic cells disposed between the transparent front layer and the flexible back sheet,
a first seal isolating the plurality of interconnected photovoltaic cells; and
a second seal isolating the moisture barrier, said second seal being distinct from said first seal.

2. The photovoltaic module of claim 1 said flexible back sheet is a multi-layer flexible back sheet comprising an insulation sheet, the electrically isolated moisture barrier, a back layer and the second seal; said insulation sheet disposed between the plurality of photovoltaic cells and the moisture barrier, said moisture barrier disposed between the insulation sheet and the back layer, and further wherein said second seal comprises a bond between the insulation sheet and the back layer and extends around the moisture barrier such that the insulation sheet, back layer and second seal electrically isolate the moisture barrier.

3. The photovoltaic module of claim 1 wherein said flexible back sheet is a multi-layer flexible back sheet comprising an insulation sheet, the electrically isolated moisture barrier and a back layer; said insulation sheet disposed between the plurality of photovoltaic cells and the moisture barrier, said moisture barrier disposed between the insulation sheet and the back layer, wherein said back layer has dimensions greater than the moisture barrier and extends past the moisture barrier to enclose an edge of the moisture barrier.

4. The photovoltaic module of claim 1 wherein said flexible back sheet is a multi-layer flexible back sheet comprising an insulation sheet, the electrically isolated moisture barrier, a back layer and the second seal; said insulation sheet disposed between the plurality of photovoltaic cells and the moisture barrier, said moisture barrier disposed between the insulation sheet and the back layer, and said second seal comprising the perimeter of the back layer.

5. The photovoltaic module of claim 1 wherein the first seal comprises a sealing material surrounding the interconnected photovoltaic cells.

6. The photovoltaic module of claim 5 wherein the first seal further comprises a bond between the sealing material and the transparent front layer.

7. The photovoltaic module of claim 6 wherein the first seal further comprises a bond between the sealing material and the flexible back sheet.

8. The photovoltaic module of claim 6 wherein said second seal comprises a bond between the sealing material and the back layer.

9. The photovoltaic module of claim 3 wherein said back layer extends past the insulation sheet to enclose an edge of the insulation sheet.

10. The photovoltaic module of claim 1 wherein at least one of the first and second seals comprises a sealing material between two module components.

11. The photovoltaic module of claim 1 wherein at least one of the first and second seals comprises an adhesive bond between two module components.

12. A photovoltaic module comprising:
a transparent front layer;
a multi-layer flexible back sheet; and
a plurality of interconnected photovoltaic cells disposed between the transparent front layer and the multi-layer flexible back sheet,
wherein said multi-layer flexible back sheet comprises an insulation sheet, an electrically isolated moisture barrier and a back layer; said insulation sheet disposed between the plurality of photovoltaic cells and the moisture barrier, said moisture barrier disposed between the insulation sheet and the back layer, wherein said back layer has dimensions greater than the moisture barrier and extends past the moisture barrier to enclose an edge of the moisture barrier.

13. The photovoltaic module of claim 12 wherein said back layer extends past the insulation sheet to enclose an edge of the insulation sheet.

14. The photovoltaic module of claim 12 further comprising an edge seal material surrounding the plurality of photovoltaic cells, wherein said edge seal material is sealed to the back layer.

15. The photovoltaic module of claim 12 wherein said insulation sheet and said back layer are arranged to fully enclose said moisture barrier.

16. A photovoltaic module comprising:
a transparent front layer;
a multi-layer flexible back sheet; and
a plurality of interconnected photovoltaic cells disposed between the transparent front layer and the multi-layer flexible back sheet,
wherein said multi-layer flexible back sheet comprises an insulation sheet, an electrically isolated moisture barrier, a back layer and a seal; said insulation sheet disposed between the plurality of photovoltaic cells and the moisture barrier, said moisture barrier disposed between the insulation sheet and the back layer, and said seal comprising the perimeter of the back layer.

17. The photovoltaic module of claim 16 wherein said seal comprises a bond between the perimeter of the back layer and a second module component.

18. The photovoltaic module of claim 17 wherein said second module component comprises an edge material that surrounds the plurality of interconnected photovoltaic cells.

19. The photovoltaic module of claim 16 wherein the back layer has dimensions greater than the moisture barrier and extends past the moisture barrier to cover the perimeter of the moisture barrier.
